(19) United States
(12) Patent Application Publication
(10) Pub. No.: US 2025/0261320 A1
(43) Pub. Date: Aug. 14, 2025

(54) ELECTRONIC DEVICE

(71) Applicant: VIVO MOBILE COMMUNICATION CO., LTD., Dongguan (CN)

(72) Inventor: Yongfa CAI, Dongguan (CN)

(73) Assignee: VIVO MOBILE COMMUNICATION CO., LTD., Dongguan (CN)

(21) Appl. No.: 19/193,944

(22) Filed: Apr. 29, 2025

Related U.S. Application Data
(63) Continuation of application No. PCT/CN2023/126097, filed on Oct. 24, 2023.

(30) Foreign Application Priority Data
Oct. 31, 2022 (CN) 202211343490.6

(51) Int. Cl. H05K 5/02

(52) U.S. Cl. CPC H05K 5/0226

(57) ABSTRACT

An electronic device is provided. The electronic device includes: a hinge assembly; a housing including a first housing, a second housing, and a hinge cover, where the hinge assembly and the hinge cover are arranged opposite to each other, the first housing and the second housing are separately connected to the hinge assembly, the first housing and the second housing are rotatably connected through the hinge assembly, and the first housing and the second housing are respectively located on two sides of the hinge cover to enclose an accommodating space for accommodating the hinge assembly; and an anti-wear layer arranged on a side of the first housing close to the hinge cover, and hardness of the anti-wear layer is lower than hardness of the hinge cover.

### CROSS-REFERENCE TO RELATED APPLICATIONS

This application is a continuation of International Application No. PCT/CN2023/126097, filed Oct. 24, 2023, which claims priority to Chinese Patent Application No. 202211343490.6, filed Oct. 31, 2022. The entire contents of each of the above-referenced applications are expressly incorporated herein by reference.

### TECHNICAL FIELD

This application relates to the field of electronic device technologies, and specifically, to an electronic device.

### BACKGROUND

In the related art, a foldable electronic device includes a hinge assembly, a hinge cover covering the hinge assembly, and a housing rotatably connected to the hinge cover. In a process in which the housing is rotated relative to the hinge assembly, a size of a display screen of the electronic device is switched, which is gradually favored by a user.

In the related art, in a process in which the housing is rotated relative to the hinge cover, friction is generated between the housing and the hinge cover. As a result, the hinge cover is easily worn, and a scratch appears on the hinge cover, affecting aesthetics of the electronic device.

### SUMMARY

This application provides an electronic device.

According to a first aspect, an embodiment of this application provides an electronic device, including: a hinge assembly; and a housing, including a first housing, a second housing, and a hinge cover, where the hinge assembly and the hinge cover are arranged opposite to each other, the first housing and the second housing are separately connected to the hinge assembly, the first housing and the second housing are rotatably connected through the hinge assembly, and the first housing and the second housing are respectively located on two sides of the hinge cover to enclose an accommodating space for accommodating the hinge assembly; and an anti-wear layer is arranged on a side of the first housing close to the hinge cover, and hardness of the anti-wear layer is lower than hardness of the hinge cover.

In embodiments of this application, the electronic device includes the hinge assembly and the housing, the housing includes the first housing, the second housing, and the hinge cover, the hinge assembly and the hinge cover are arranged opposite to each other, and the first housing and the second housing can be rotated relative to the hinge assembly, to cause the electronic device to be in a folded state or an unfolded state. The first housing and the second housing are respectively located on the two sides of the hinge cover, and enclose the accommodating space, to accommodate the hinge assembly. The anti-wear layer is arranged on the side of the first housing close to the hinge cover, and the hardness of the anti-wear layer is lower than the hardness of the hinge cover. In this way, in a process in which the first housing is rotated relative to the hinge assembly, the anti-wear layer can prevent the first housing from wearing the hinge cover, thereby improving aesthetics of the electronic device.

Additional aspects and advantages of this application are partially provided in the following description, and partially become apparent in the following description or are learned through practice of this application.

### BRIEF DESCRIPTION OF THE DRAWINGS

The foregoing and/or additional aspects and advantages of this application become apparent and comprehensible in the following description of the embodiments made with reference to the following accompanying drawings.

FIG. 1 is a schematic structural diagram of a framework according to an embodiment of this application;

FIG. 2 is a schematic structural diagram of a framework and an anti-wear layer according to an embodiment of this application;

FIG. 3 is a partial schematic structural diagram of the embodiment shown in FIG. 2;

FIG. 4 is a schematic structural diagram 1 of an electronic device according to an embodiment of this application;

FIG. 5 is a partial schematic structural diagram of the embodiment shown in FIG. 4;

FIG. 6 is a schematic structural diagram 2 of an electronic device according to an embodiment of this application;

FIG. 7 is a partial schematic structural diagram of the embodiment shown in FIG. 6;

FIG. 8 is a schematic structural diagram 3 of an electronic device according to an embodiment of this application;

FIG. 9 is a partial schematic structural diagram of the embodiment shown in FIG. 8;

FIG. 10 is a schematic structural diagram 4 of an electronic device according to an embodiment of this application;

FIG. 11 is a partial schematic structural diagram of the embodiment shown in FIG. 10;

FIG. 12 is a schematic structural diagram 5 of an electronic device according to an embodiment of this application; and

FIG. 13 is a partial schematic structural diagram of the embodiment shown in FIG. 12.

### REFERENCE SIGNS

1: hinge assembly;

2: hinge cover;

3: housing;

30: first housing;

31: second housing;

32: sink groove;

34: limiting boss;

4: anti-wear layer;

40: first end;

42: second end;

44: connecting portion;

46: protruding portion; and

48: arc segment.

### DETAILED DESCRIPTION

Embodiments of this application are described in detail below, and examples of the embodiments are shown in the accompanying drawings, where the same or similar elements or the elements having same or similar functions are denoted by the same or similar reference numerals throughout the description. The following embodiments described with reference to the accompanying drawings are exemplary, and are used merely for explaining this application, and cannot be construed as a limit to this application. All other embodiments derived by a person of ordinary skill in the art based on the embodiments of this application without creative efforts shall fall within the protection scope of this application.

In the description of this application, unless stated otherwise, the meaning of “a plurality of” is two or more than two. In addition, “and/or” in this specification and the claims represents at least one of connected objects.

In the description of this application, it should be understood that orientation or position relationships indicated by the terms such as “axial” and “circumferential” are based on orientation or position relationships shown in the accompanying drawings, and are used only for ease and brevity of illustration and description of this application, rather than indicating or implying that the mentioned apparatus or component needs to have a particular orientation or needs to be constructed and operated in a particular orientation. Therefore, such terms should not be construed as a limit to this application.

In the description of this application, it should be noted that, unless otherwise explicitly specified or defined, the term “connection” should be understood in a broad sense. For example, the connection may be a fixed connection, a detachable connection, or an integral connection; or the connection may be a mechanical connection or an electrical connection; or the connection may be a direct connection, an indirect connection through an intermediary, or internal communication between two components. A person of ordinary skill in the art may understand specific meanings of the foregoing terms in this application according to a specific situation.

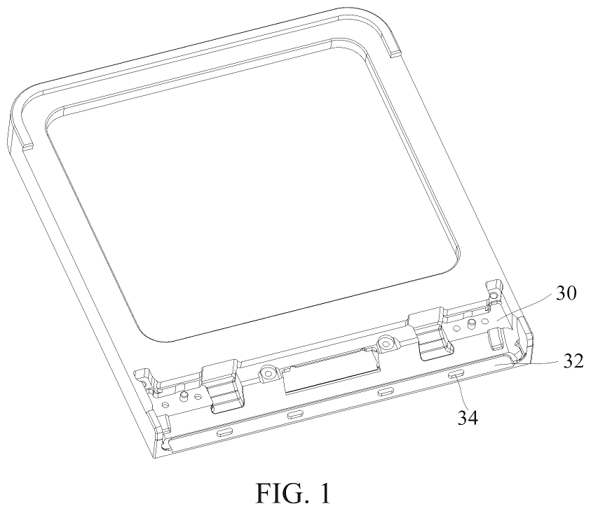

An electronic device according to the embodiments of this application is described below with reference to FIG. 1 to FIG. 13.

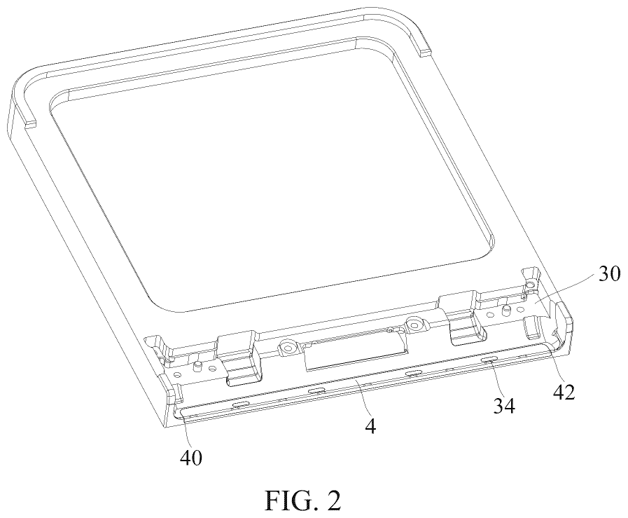

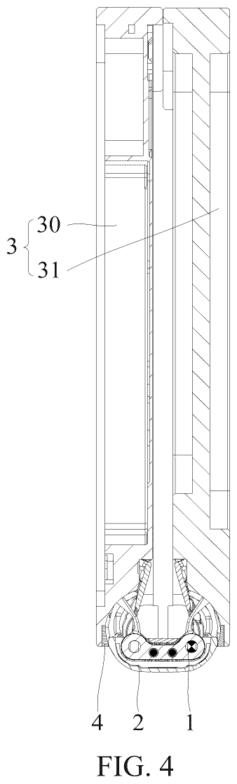

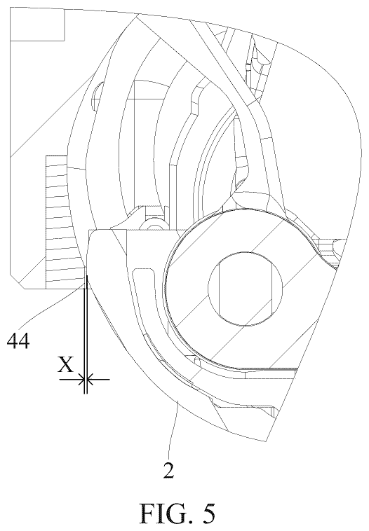

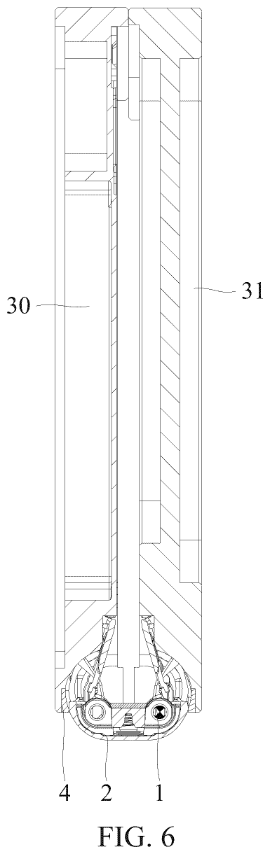

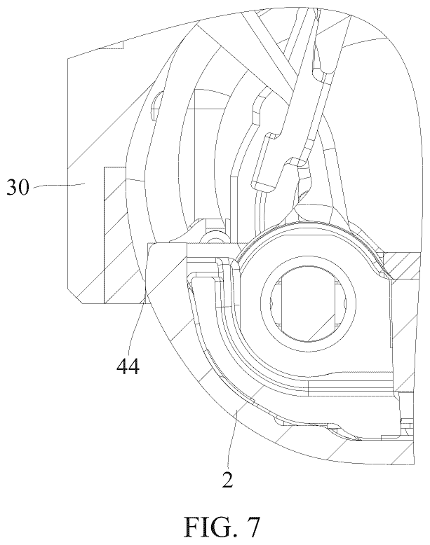

As shown in FIG. 1, FIG. 2, FIG. 4, FIG. 5, FIG. 6, and FIG. 7, the electronic device according to some embodiments of this application includes: a hinge assembly 1; and a housing 3, including a first housing 30, a second housing 31, and a hinge cover 2, where the hinge assembly 1 and the hinge cover 2 are arranged opposite to each other, the first housing 30 and the second housing 31 are separately connected to the hinge assembly 1, the first housing 30 and the second housing 31 are rotatably connected through the hinge assembly 1, and the first housing 30 and the second housing 31 are respectively located on two sides of the hinge cover 2 to enclose an accommodating space for accommodating the hinge assembly 1; and an anti-wear layer 4 is arranged on a side of the first housing 30 close to the hinge cover 2, and hardness of the anti-wear layer 4 is lower than hardness of the hinge cover 2.

In the embodiments of this application, the electronic device includes the hinge assembly 1 and the housing 3, the housing 3 includes the first housing 30, the second housing 31, and the hinge cover 2, the hinge assembly 1 and the hinge cover 2 are arranged opposite to each other, and the first housing 30 and the second housing 31 can be rotated relative to the hinge assembly 1, to cause the electronic device to be in a folded state or an unfolded state. The first housing 30 and the second housing 31 are respectively located on the two sides of the hinge cover 2, and enclose the accommodating space, to accommodate the hinge assembly 1. The anti-wear layer 4 is arranged on the side of the first housing 30 close to the hinge cover 2, and the hardness of the anti-wear layer 4 is lower than the hardness of the hinge cover 2. In this way, in a process in which the first housing 30 is rotated relative to the hinge assembly 1, the anti-wear layer 4 can prevent the first housing 30 from wearing the hinge cover 2, thereby improving aesthetics of the electronic device.

Further, the anti-wear layer 4 is arranged on both the side of the first housing 30 close to the hinge cover 2 and a side of the second housing 31 close to the hinge cover 2.

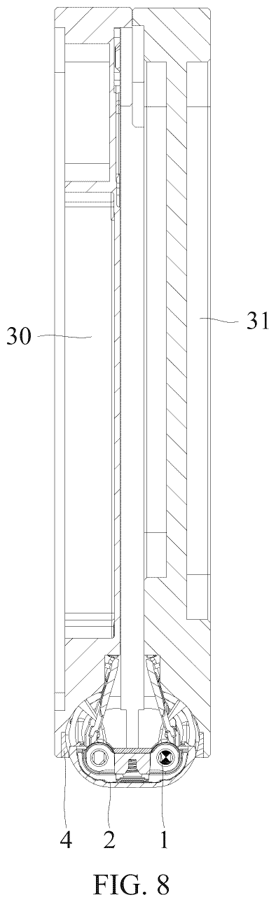

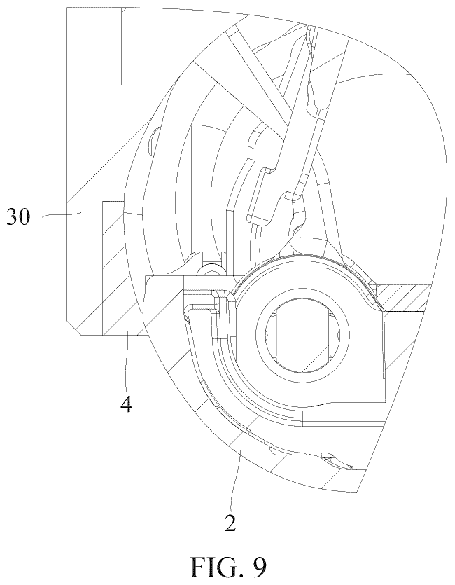

As shown in FIG. 4, FIG. 5, FIG. 6, FIG. 7, FIG. 8, and FIG. 9, according to some embodiments, when the electronic device is in the folded state, the anti-wear layer 4 abuts against the hinge cover 2.

In the embodiments, in a case that the electronic device is in the folded state, the anti-wear layer 4 abuts against the hinge cover 2, so that a gap between the first housing and the hinge cover 2 is reduced, thereby improving the aesthetics of the electronic device.

It may be understood that, in a process in which the first housing 30 and the second housing 31 are rotated relative to the hinge cover 2, the electronic device can be switched between the folded state and the unfolded state. In some embodiments, in the folded state, the first housing 30 and the second housing 31 are located on the two sides of the hinge cover 2, and the first housing 30 is in contact with a side surface of the hinge cover 2 facing away from the accommodating space. Because the anti-wear layer 4 is arranged on the side of the first housing 30 close to the hinge cover 2, and the anti-wear layer 4 abuts against the hinge cover 2 in the folded state, the gap between the first housing 30 and the hinge cover 2 can be reduced or eliminated in the folded state, thereby preventing dust from entering the electronic device from the gap, and preventing the gap between the first housing 30 and the hinge cover 2 from exposing an internal component. Correspondingly, in the unfolded state, the first housing 30 and the second housing 31 cover an outer side of the hinge cover 2, so that the gap between the first housing 30 and the hinge cover 2 and a gap between the second housing 31 and the hinge cover 2 do not exist or are small, and the internal component is not easily exposed. Therefore, through the electronic device provided in this application, in both the folded state and the unfolded state, the gap between the first housing 30 and the hinge cover 2 can be optimized, thereby improving the aesthetics of the electronic device.

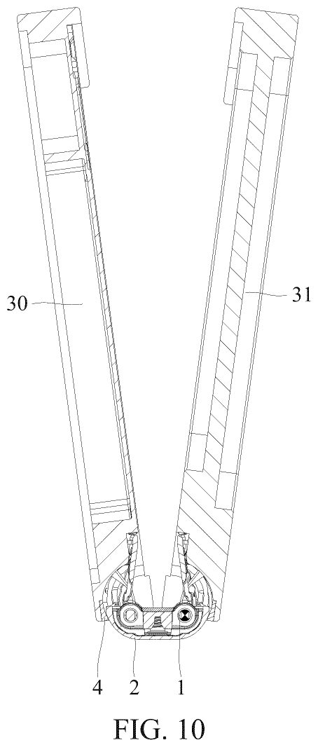

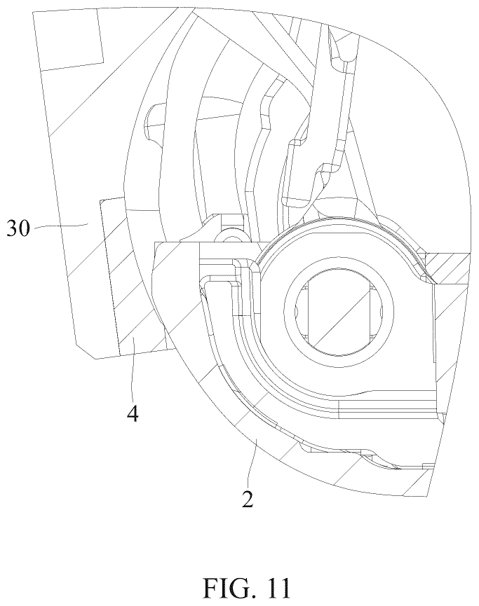

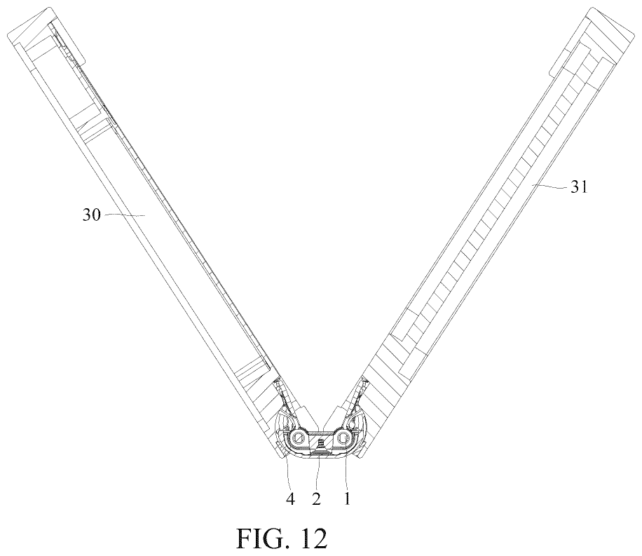

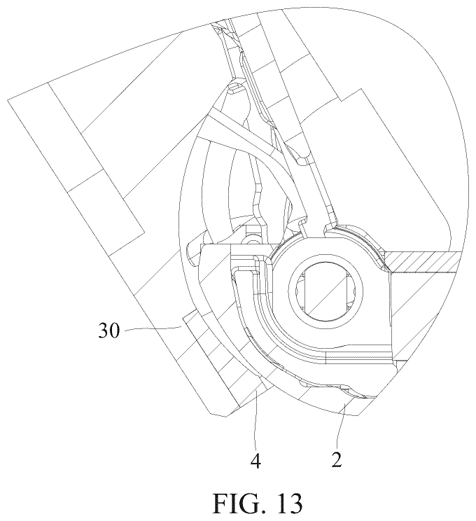

As shown in FIG. 10, FIG. 11, FIG. 12, and FIG. 13, according to some embodiments of this application, in a process in which the electronic device is switched from the folded state to the unfolded state, the anti-wear layer 4 keeps abutting against the hinge cover 2, and the anti-wear layer 4 moves along the side surface of the hinge cover 2 facing away from the accommodating space.

In the embodiments, in the process in which the electronic device is switched from the folded state to the unfolded state, the anti-wear layer 4 keeps abutting against the hinge cover 2, to cause the first housing 30 to be always in contact with the hinge cover 2 through the anti-wear layer 4. In this way, the first housing 30 can be prevented from wearing the hinge cover 2. In addition, the gap between the first housing 30 and the hinge cover 2 can be reduced, thereby preventing dust from entering from the gap in a process in which the electronic device is unfolded or folded, thereby improving the aesthetics of the electronic device.

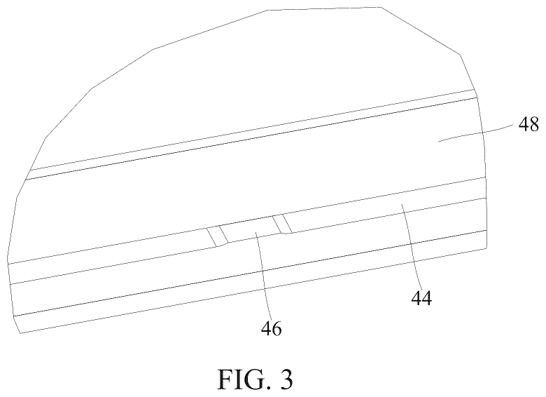

As shown in FIG. 3, according to some embodiments of this application, the anti-wear layer 4 includes a protruding portion 46 protruding facing the hinge cover 2, and the protruding portion 46 abuts against the hinge cover 2.

In the embodiments, the anti-wear layer 4 includes the protruding portion 46, and the protruding portion 46 abuts against the hinge cover 2. In this way, in the process in which the first housing 30 is rotated, the protruding portion 46 is in contact with the hinge cover 2, avoiding unstableness of a contact area between the first housing 30 and the hinge cover 2 caused by a flatness problem of the first housing 30, thereby avoiding friction and noise in the process in which the first housing 30 is rotated.

As shown in FIG. 2 and FIG. 3, according to some embodiments of this application, the anti-wear layer 4 includes a plurality of protruding portions 46 arranged at intervals and a connecting portion 44 connecting two adjacent protruding portions 46, and the protruding portions 46 and the connecting portion 44 are integrally connected.

In the embodiments, the anti-wear layer 4 includes the plurality of protruding portions 46 arranged at intervals and the connecting portion 44 connecting two adjacent protruding portions 46. In this way, in the process in which the first housing 30 is rotated relative to the hinge cover 2, the protruding portion 46 is in contact with the hinge cover 2, to prevent the first housing 30 from wearing the hinge cover 2. In addition, through arrangement of the connecting portion 44, a gap between a part of the first housing 30 without the protruding portion 46 and the hinge cover 2 can be reduced, thereby improving the aesthetics of the electronic device.

In addition, the connecting portion 44 is connected to adjacent protruding portions 46, and the connecting portion 44 and the protruding portions 46 are integrally formed. It may be understood that, both hardness of the connecting portion 44 and hardness of the protruding portion 46 are less than the hardness of the hinge cover 2. Therefore, in the process in which the first housing 30 is switched between the folded state and the unfolded state, if the protruding portion 46 is worn, the connecting portion 44 abuts against the hinge cover 2, so that the hinge cover 2 can also be prevented from being worn.

In some embodiments, the plurality of protruding portions 46 are arranged at intervals in an axial direction of the hinge assembly 1.

Further, a position at which the protruding portion 46 is arranged is not limited. Therefore, there may be a plurality of protruding portions 46, to reduce a probability that the protruding portion 46 is worn.

In some embodiments, a quantity of the protruding portions 46 is greater than or equal to 4. Further, the quantity of the protruding portions 46 is greater than or equal to 6. In some embodiments, the quantity of the protruding portions 46 is any of 7, 8, 9, 10, 12, 15, 20, and 30.

Further, FIG. 8, FIG. 9, FIG. 10, FIG. 11, FIG. 12, and FIG. 13 show schematic cross-sectional views of positions at which the protruding portions 46 cooperate with the hinge cover 2 in a process in which the first housing 30 and the second housing 31 are rotated relative to the hinge assembly 1 to cause the electronic device to be folded or unfolded. The entire electronic device is changed from a folded state shown in FIG. 8 and FIG. 9, through a state shown in FIG. 10 and FIG. 11, and finally to a state shown in FIG. 12 and FIG. 13. During the entire rotation, only friction and contact between the protruding portions 46 and the hinge cover 2 exist. In addition, the plurality of protruding portions 46 can be arranged in this application. The arrangement of the plurality of protruding portions 46 can also alleviate, to a certain extent, a problem that the protruding portions 46 are easily worn.

As shown in FIG. 2, in an exemplary design, in a rotation axial direction of the first housing 30, the anti-wear layer 4 includes a first end 40 and a second end 42. The first end 40 and the second end 42 are arranged respectively corresponding to two ends of the hinge cover 2. One of the first end 40 or the second end 42 protrudes from the hinge cover 2, and the other is aligned with the hinge cover 2. In some embodiments, both the first end 40 and the second end 42 protrude from the hinge cover 2, or both the first end 40 and the second end 42 are aligned with the hinge cover 2.

In the embodiments, in the rotation axial direction of the first housing 30, the anti-wear layer 4 includes the first end 40 and the second end 42, and the first end 40 and the second end 42 are arranged respectively corresponding to the two ends of the hinge cover 2. In some embodiments, one of the first end 40 or the second end 42 of the anti-wear layer 4 protrudes from the hinge cover 2, and the other is aligned with the hinge cover 2, so that in the process in which the first housing 30 is rotated, the anti-wear layer 4 always abuts against the hinge cover 2. In this way, effect of protecting the hinge cover 2 by the anti-wear layer 4 can be improved, and the first housing 30 is prevented from directly being in contact with the hinge cover 2.

In a case that both the first end 40 and the second end 42 protrude from the hinge cover 2, the anti-wear layer 4 is longer than the hinge cover 2, thereby improving the effect of protecting the hinge cover 2 and preventing the first housing 30 from directly being in contact with the hinge cover 2.

In a case that both the first end 40 and the second end 42 are aligned with the hinge cover 2, a length of the anti-wear layer 4 is the same as that of the hinge cover 2, thereby ensuring the effect of protecting the hinge cover 2 and preventing the first housing 30 from directly being in contact with the hinge cover 2.

It should be noted that, in the rotation axial direction of the first housing 30, the hinge cover 2 includes a third end and a fourth end, the third end is arranged corresponding to the first end 40, and the fourth end is arranged corresponding to the second end 42. In other words, in the rotation axial direction of the first housing 30, the first end 40 protrudes from the third end and the second end 42 protrudes from the fourth end, or the first end 40 protrudes from the third end and the second end 42 is aligned with the fourth end, or the first end 40 is aligned with the third end and the second end 42 protrudes from the fourth end, or the first end 40 is aligned with the third end and the second end 42 is aligned with the fourth end.

Each area in which the first housing 30 may be in contact with the hinge cover 2 is on the anti-wear layer 4, so that theoretically, there is no problem of wearing the hinge cover 2. In principle, there is no wearing problem. Therefore, a gap X between the connecting portion 44 of the anti-wear layer 4 other than the protruding portion 46 and the hinge cover 2 can be made very small, to reduce the gap between the first housing 30 and the hinge cover 2, thereby improving delicacy of the entire electronic device and effectively resolving a problem that the aesthetics is affected due to exposure of a structure member by the gap and a dust prevention effect is poor.

The plurality of protruding portions 46 are designed on a part of the anti-wear layer 4, and the quantity of the protruding portions is not limited by space. Cooperation of the plurality of protruding portions 46 can alleviate, to a certain extent, a problem that the protruding portions 46 are quickly worn. Compared to a solution in which a wear-resistant member is assembled on the first housing 30 by adhesive dispensing, the electronic device provided in this application has higher dimensional precision, the protruding portion 46 does not have a problem of floating or falling off caused by adhesive dispensing, and mass production consistency is better.

According to some embodiments of this application, a height of the protruding portion 46 is greater than or equal to 0.03 mm, and the height of the protruding portion 46 is less than or equal to 0.3 mm.

In the embodiments, if the height of the protruding portion 46 is too large, the gap X is caused to be too large. As a result, dust easily enters. In a case that the electronic device is in the folded state, the internal component is further easily exposed. In addition, if the height of the protruding portion 46 is too large, the aesthetics is affected. If the height of the protruding portion 46 is too small, wearing of the protruding portion 46 is accelerated. Therefore, the height of the protruding portion 46 is set to be greater than or equal to 0.03 mm, and be less than or equal to 0.3 mm. This ensures the aesthetics of the electronic device, prevents the dust from entering from the gap, prevents the internal component from being exposed, and can further prevent the protruding portion 46 from being worn too soon.

In specific application, the height of the protruding portion 46 is any value of 0.03 mm, 0.05 mm, 0.06 mm, 0.07 mm, 0.08 mm, 0.1 mm, 0.12 mm, 0.15 mm, 0.18 mm, 0.2 mm, 0.25 mm, and 0.3 mm.

Correspondingly, as shown in FIG. 5, the gap X between the connecting portion 44 and the hinge cover 2 is greater than or equal to 0.03 mm, and is less than or equal to 0.3 mm.

In the embodiments, if the gap X is too large, dust easily enters. In a case that the electronic device is in the folded state, the internal component is further easily exposed. In addition, if the gap X is too large, the aesthetics is affected. If the gap is too small, wearing of the protruding portion 46 is accelerated. Therefore, the gap X is set to be greater than or equal to 0.03 mm, and be less than or equal to 0.3 mm. This ensures the aesthetics of the electronic device, prevents the dust from entering from the gap, prevents the internal component from being exposed, and can further prevent the protruding portion 46 from being worn too soon.

In specific application, a size of the gap X is any value of 0.03 mm, 0.05 mm, 0.06 mm, 0.07 mm, 0.08 mm, 0.1 mm, 0.12 mm, 0.15 mm, 0.18 mm, 0.2 mm, 0.25 mm, and 0.3 mm.

According to some embodiments of this application, a sink groove 32 is provided on the first housing 30, the anti-wear layer 4 is arranged in the sink groove 32, a plurality of limiting bosses 34 are arranged in the sink groove 32, limiting holes are formed on the anti-wear layer 4, and the anti-wear layer 4 is connected to the first housing 30 through the limiting holes and the limiting bosses 34.

In the embodiments, the sink groove 32 is provided on the first housing 30, and the plurality of limiting bosses 34 are arranged in the sink groove 32. In addition, the limiting holes are provided on the anti-wear layer 4, and the limiting boss 34 is mounted in the limiting hole, to cause the anti-wear layer 4 to be connected to the first housing 30, and improve strength of connection between the anti-wear layer 4 and the first housing 30, thereby preventing the anti-wear layer 4 from falling off.

Further, the protruding portions 46 and the connecting portion 44 are integrally formed through injection molding.

In the embodiments, the protruding portions 46 and the connecting portion 44 are integrally formed through injection molding. This improves strength of connection between the protruding portions 46 and the connecting portion 44, thereby ensuring reliability of contact between the anti-wear layer 4 and the hinge cover 2.

In addition, the protruding portion 46 is directly molded on the first housing 30 through an injection molding process that has achieved high-precision control. This can ensure that the height of the protruding portion 46 protruding from the first housing 30 can be precisely controlled, to ensure that the gap X between the connecting portion 44 and the hinge cover 2 can be designed to be far smaller than a gap between a housing and a hinge cover in the prior art. Therefore, in the case that the electronic device is in the folded state, the gap between the first housing 30 and the hinge cover 2 can be significantly reduced.

According to some embodiments of this application, the hardness of the anti-wear layer 4 is lower than hardness of the first housing 30.

In the embodiments, the hardness of the anti-wear layer 4 is lower than the hardness of the first housing 30, thereby ensuring reliability of connection between the first housing 30 and the anti-wear layer 4. In addition, if the anti-wear layer 4 and the first housing 30 are loosely connected, the anti-wear layer 4 can be further prevented from wearing the first housing 30.

As shown in FIG. 3, according to some embodiments of this application, the anti-wear layer 4 further includes: an arc segment 48. The arc segment 48 is arranged recessed facing the first housing 30.

In the embodiments, the anti-wear layer 4 further includes the arc segment 48, and the arc segment 48 is arranged recessed facing the first housing 30, to avoid the hinge cover 2 in the process in which the first housing 30 is rotated relative to the hinge cover 2. In addition, protection can be performed in a range of movement of the hinge cover 2 relative to the first housing, thereby preventing the hinge cover 2 from being in contact with the first housing 30 and preventing the first housing 30 from wearing the hinge cover 2.

In specific application, in a process in which the electronic device is unfolded or folded, the arc segment 48 can perform protection in the range of movement of the hinge cover 2 relative to the first housing 30, to prevent the hinge cover 2 from directly being in contact with the first housing 30.

According to some embodiments of this application, the anti-wear layer 4 is a plastic layer or a plastic layer with a lubricating layer on a surface facing the hinge cover 2.

In the embodiments, the anti-wear layer 4 is a plastic layer, so that the anti-wear layer 4 has certain flexibility, thereby preventing the hinge cover 2 from being worn. In some embodiments, a plastic layer with a lubricating layer is arranged on a surface of the anti-wear layer 4 facing the hinge cover 2, so that the anti-wear layer 4 can have certain flexibility and can further have certain lubricity, thereby further reducing a possibility of wearing the hinge cover 2.

In specific application, in this application, by using a principle that a plastic material with low Mohs hardness and a self-lubricating property cannot easily scratch a metal material with high Mohs hardness, an area in which the first housing 30 may be in contact with the hinge cover 2 is partially disassembled into the anti-wear layer 4 made of a plastic material with low Mohs hardness and a self-lubricating property. In the process in which the first housing 30 is rotated, the first housing 30 does not scratch an appearance surface of the hinge cover 2, and additionally, the gap between the hinge cover 2 and the first housing 30 is greatly reduced. In addition, the problem that the anti-wear layer 4 is easily worn is alleviated, and the problems of the exposure of the structure member and dust ingress that are caused by the large gap between the first housing 30 and the hinge cover 2 are resolved.

The sink groove 32 is provided on the first housing 30 for injection molding of plastic of low Mohs hardness. In addition, the plurality of limiting bosses 34 are designed, to enhance bonding force between the anti-wear layer 4 and a metal part of the first housing 30 after the injection molding.

Further, the sink groove 32 is in a step shape, and the anti-wear layer 4 made of the plastic material with low Mohs hardness is injection-molded on the sink groove 32. A plurality of protruding portions 46 are arranged near an edge of the step, to further alleviate, after the gap between the first housing 30 and the hinge cover 2 is reduced, a problem that there may be friction and noise caused by unstableness of the contact area between the first housing 30 and the hinge cover 2 due to a processing flatness error of the first housing 30.

It should be noted that, the electronic device may be a smart phone, a tablet computer, an electronic reader, a wearable device, or the like. Examples are not listed one by one herein.

In the description of this specification, description using reference terms “an embodiment”, “some embodiments”, “an exemplary embodiment”, “an example”, “a specific example”, or “some examples” means that specific characteristics, structures, materials, or features described with reference to the embodiment or example are included in at least one embodiment or example of this application. In this specification, schematic description of the foregoing terms does not necessarily point at a same embodiment or example. Moreover, the specific features, structures, materials, or characteristics described may be combined in any one or more embodiments or examples in an appropriate manner.

Although the embodiments of this application have been shown and described, a person of ordinary skill in the art may understand that various changes, modifications, replacements, and variations may be made to the embodiments without departing from the principles and spirit of this application, and the scope of this application is as defined by the appended claims and their equivalents.

What is claimed is:

1. An electronic device, comprising:
a hinge assembly;
a housing, comprising a first housing, a second housing, and a hinge cover, wherein the hinge assembly and the hinge cover are arranged opposite to each other, the first housing and the second housing are separately connected to the hinge assembly, the first housing and the second housing are rotatably connected through the hinge assembly, and the first housing and the second housing are respectively located on two sides of the hinge cover to enclose an accommodating space for accommodating the hinge assembly; and
an anti-wear layer, arranged on a side of the first housing close to the hinge cover, wherein hardness of the anti-wear layer is lower than hardness of the hinge cover.

2. The electronic device according to claim 1, wherein the anti-wear layer abuts against the hinge cover when the electronic device is in a folded state.

3. The electronic device according to claim 2, wherein in a process in which the electronic device is switched from the folded state to an unfolded state, the anti-wear layer keeps abutting against the hinge cover and the anti-wear layer moves along a side surface of the hinge cover facing away from the accommodating space.

4. The electronic device according to claim 2, wherein the anti-wear layer comprises a protruding portion protruding facing the hinge cover, and the protruding portion abuts against the hinge cover.

5. The electronic device according to claim 4, wherein the anti-wear layer comprises a plurality of protruding portions arranged at intervals and a connecting portion connecting two adjacent protruding portions, and the protruding portions and the connecting portion are integrally connected.

6. The electronic device according to claim 4, wherein a height of the protruding portion is greater than or equal to 0.03 mm, and the height of the protruding portion is less than or equal to 0.3 mm.

7. The electronic device according to claim 1, wherein a sink groove is provided on the first housing, the anti-wear layer is arranged in the sink groove, a plurality of limiting bosses are arranged in the sink groove, limiting holes are formed on the anti-wear layer, and the anti-wear layer is connected to the first housing through the limiting holes and the limiting bosses.

8. The electronic device according to claim 1, wherein the hardness of the anti-wear layer is lower than hardness of the first housing.

9. The electronic device according to claim 1, wherein the anti-wear layer further comprises:
an arc segment, wherein the arc segment is arranged recessed facing the first housing.

10. The electronic device according to claim 1, wherein the anti-wear layer is a plastic layer or a plastic layer with a lubricating layer on a surface facing the hinge cover.
